(19) United States
(12) Patent Application Publication
(10) Pub. No.: US 2005/0189656 A1
(43) Pub. Date: Sep. 1, 2005

(54) Micro-vias for electronic packaging

(76) Inventor: Chun Yee Tan, Perak (MY)

Correspondence Address: TROP PRUNER & HU, PC, 8554 KATY FREEWAY, SUITE 100, HOUSTON, TX, 77024, US

(21) Appl. No.: 10/787,625

(22) Filed: Feb. 26, 2004

(51) Int. Cl. H01L 23/48

(52) U.S. Cl. 257/774; 438/629

(57) ABSTRACT

Micro-vias may be formed, for example, using laser drilling, through a dielectric layer, down to and partially through an underlying capture pad. As a result, when the micro-via is filled with a conductor, stress cracking may be reduced in some embodiments. The stress cracking may be reduced by the increased interface area between the capture pad and the micro-via in some embodiments. Stress cracking may also be reduced due to the more complex shape of the interface between the via and the capture pad.

### BACKGROUND

This invention relates generally to packaging for electronic components.

Integrated circuit devices may be packaged with very high input/output contact counts. For example, in high density electronic packaging, micro-vias may be utilized to connect to interconnection layers. A micro-via is any via with a diameter that is 6 mil or less. The micro-via may extend through a dielectric which connects to a conductive layer.

A micro-via may be formed, for example, by photo-definition, plasma, or laser drilling. Conventionally, the micro-via is drilled through a dielectric layer down to a capture pad that may be formed of copper. A seed layer may line the via and then the via may be filled with a metal.

Micro-via reliability has been a concern in high density organic packaging as micro-vias become smaller. One key failure mode is micro-via delamination. Delamination may occur when the bottom of the micro-via separates from the capture pad. This may be due to peeling stresses applied to the micro-via and capture pad interface by material expansion and contraction during thermal treatment for reliability testing.

Thus, there is a need for better ways to form micro-vias for electronic packaging.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional view at a subsequent stage of manufacture in accordance with one embodiment of the present invention;

FIG. 3 is an enlarged, cross-sectional view at a subsequent stage of manufacture in accordance with one embodiment of the present invention; and

FIG. 4 is an enlarged, cross-sectional view at a subsequent stage of manufacture in accordance with one embodiment of the present invention.

### DETAILED DESCRIPTION

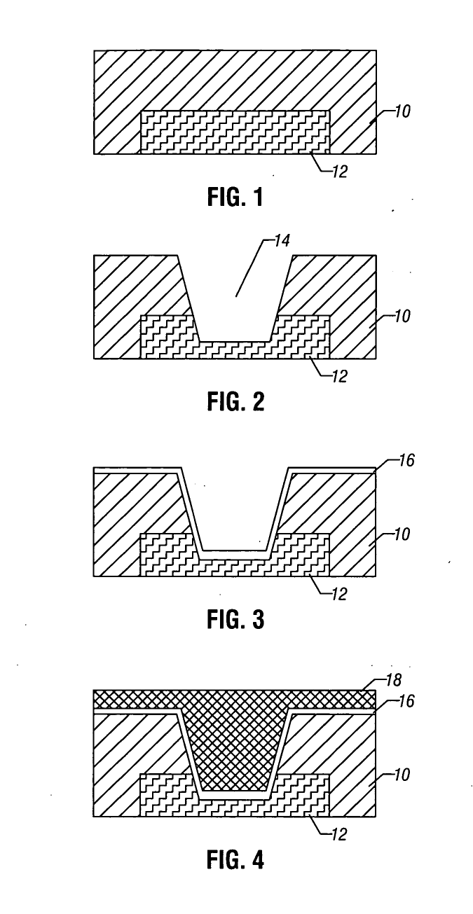

Referring to FIG. 1, an electronic package may include a capture pad 12. In one embodiment, the capture pad 12 may be a copper pad that allows connections to an underlying interconnect layer. The capture pad 12 may be covered by a buildup layer 10 formed of a dielectric. For example, the dielectric may be Ajinomoto buildup film (ABF). However, any other dielectric material may also be used.

Referring to FIG. 2, a micro-via 14 is drilled through the dielectric 10 and into, and partially through, the capture pad 12. The via 14 may be formed by any conventional technique, including laser and mechanical drilling. In one embodiment, a high intensity laser, such as a YAG laser, may be utilized to create the via 14 in the capture pad 12 and the dielectric 10. As a result, the via 14 extends into the capture pad 12. In one embodiment, the via 14 may taper as it extends downwardly through the dielectric 10 and into, and partially through, the capture pad 12.

Thereafter, the surface of the dielectric 10 and the surface of the via 14 may be coated with a seed layer 16 as shown in FIG. 3. In one embodiment, the seed layer 16 may be electroless copper plating. A desmear step may precede the copper plating step in one embodiment of the present invention.

Thereafter, an interconnect layer 18 may be formed as shown in FIG. 4. In one embodiment, the layer 18 may be formed by electrolytic copper plating. The plating forms on top of the seed layer 16 and, particularly, over the dielectric layer 10, filling the via 14. Thus, the resulting via 14 extends over and down through the dielectric layer 10 into the capture pad 12 as shown in FIG. 4.

In some embodiments, the formation of the via 14 inside the capture pad 12 may reduce the stress applied to the micro-via 14 and capture pad 12 interface, caused, for example, by material expansion and contraction during thermal treatment or reliability testing. This is because the surface area of contact between the capture pad 12 and the layer 18 is increased due to the insertion of the layer 18 into the capture pad 12. In addition, failure cracks may be reduced because the cracks cannot form in a simple straight line but, instead, must follow the more tortuous, U-shaped contour of the interface between the layer 18 and the capture pad 12. That interface extends vertically downwardly on the left, into the capture pad 12, horizontally along the interface between the capture pad 12 and the layer 18 and then back upwardly along the interface of the capture pad 12 and the layer 18 on the opposite side. As a result, in some embodiments, stress cracking may be reduced. This may improve the reliability of the resulting micro-vias.

In one embodiment, high density buildup packaging may be more reliable due to-improved micro-via integrity. As micro-vias become smaller and smaller, the need to improve reliability will increase.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
forming a micro-via through a dielectric layer;
continuing the micro-via into and partially through a capture pad below the dielectric layer; and
filling the micro-via with a conductive material.

2. The method of claim 1 including using an electroless plating technique to provide a seed layer before filling said micro-via.

3. The method of claim 2 including filling said micro-via using electrolytic plating.

4. The method of claim 1 including using laser drilling to form said micro-via.

5. The method of claim 1 including forming a tapered micro-via.

6. A method comprising:
forming a micro-via through a dielectric layer and into and partially through an underlying capture pad.

7. The method of claim 6 including using an electroless plating technique to provide a seed layer before filling said micro-via.

8. The method of claim 7 including filling said micro-via using electrolytic plating.

9. The method of claim 6 including using laser drilling to form said micro-via.

10. The method of claim 1 including forming a tapered micro-via.

11. A semiconductor structure comprising:
a dielectric layer;
a capture pad under said layer; and
a micro-via formed through said dielectric layer and into said capture pad, said micro-via having a conductive material.

12. The structure of claim 11 wherein said micro-via is tapered.

13. The structure of claim 11 including a seed layer between said conductive material and said micro-via.

14. The structure of claim 11 wherein said conductive material interfaces with said capture pad in a U-shape.

15. The structure of claim 11 wherein said micro-via is laser drilled.
